(19) United States
(12) Patent Application Publication
(10) Pub. No.: US 2005/0069066 A1
(43) Pub. Date: Mar. 31, 2005

(54) Method and system for estimating frequency offset for carrier-modulation digital communications system

(76) Inventors: Raimud Meyer, Furth (DE); Robert Schober, Erlangen (DE); Wolfgang Gerstacker, Nurnberg (DE)

Correspondence Address: Antonelli Terry;Stout & Kraus, Suite 1800, 1300 North Seventeenth Street, Arlington, VA, 22209, US

(21) Appl. No.: 10/495,627

(22) PCT Filed: Nov. 13, 2002
(86) PCT No.: PCT/EP02/12712

(30) Foreign Application Priority Data
Nov. 16, 2001 (EP) 01127242.4

(51) Int. Cl. H03K 7/02

(52) U.S. Cl. 375/353

(57) ABSTRACT

The present invention relates to a method and a system for estimation of the frequency offset in the digital transmission which is applicable for arbitrary linear modulations, dispersive channels, and general additive impairments. In a first step of the method N derivatives of the received signal are formed through discrete frequency shifts. Subsequently, these derivatives are preprocessed and equalized in an appropriate manner. On the basis of reliability information about the corresponding reconstructed symbol sequences, which is given in the form of metrics Mᵥ which are obtained from internal variables of the equalizer (in case of hard-output equalization) or its output values (in case of soft-output equalization), an estimate of the frequency offset can be established by analysing them in connection with the N corresponding frequency shifts fᵥ. Herein it is to be noted that the N equalizations do not necessarily have to equalize the entire received signal, but only part thereof. In this way, a frequency offset estimation can be carried out with a moderate complexity involved. After the estimation, the frequency offset is compensated and a conventional preprocessing and equalization is performed.

The present invention relates to methods and systems for carrier-modulated digital transmission, which is used e.g. in the mobile radio communication system GSM (Global System for Mobile Communication). In particular, it concerns a method and a system for frequency offset estimation for TDMA (time division multiple access) and/or FDMA (frequency division multiple access) transmission, which can be at least approximately described by pulse amplitude modulation.

In carrier-based digital transmission via dispersive channels, e.g. via a mobile radio communication channel or two-wire lines, unavoidable deviations of the carrier frequency of the received signal from the reference frequency effective at the receiver occur in real systems. These deviations are caused by both the tolerances of the frequency standards (oscillators) at the transmitter or the receiver and frequency shifts due to the motion of the transmitter and/or the receiver. The effect occurring herewith is referred to as the so-called Doppler effect and can cause both a simple shift of the transmitted frequency as well as a superposition of an infinite number of infinitesimally small received signal components with different frequency shifts (Doppler spread). If not compensated appropriately, such a frequency offset degrades the performance of the receiver with respect to the reconstruction of the transmitted data sequence significantly. This manifests itself in an increase of the bit and block error rate. If the frequency offset is known, it can be appropriately compensated in the receiver and thus the performance of the receiver can be significantly improved. Herefor several methods are known.

An overview of the current state of the art is given e.g. in U. Mengali and A. N. D'Andrea, “Synchronisation Techniques for Digital Receivers”, Plenum Press, New York, 1997. The method with the theoretically best performance (“Data Aided Maximum Likelihood Frequency Estimation”) requires a two-step search algorithm and is computationally very expensive. Therefore, this method is not used in practice. Simplified versions thereof which are based on also use data-aided estimation of the frequency offset, as e.g. disclosed in S. Kay, “A Fast and Accurate Single Frequency Estimator”, IEEE Trans. Acoust. Speech, Signal Processing, ASSP-37, pp. 1987-1990, December 1989, in M. P. Fitz, “Further Results in the Fast Estimation of a Single Frequency”, IEEE Trans. Comm., COM-42, pp. 862-864, March 1994, and in M. Luise and R. Reggiannini, “Carrier Frequency Recovery in All-Digital Modems for Burst-Mode Transmission”, IEEE Trans. Comm., COM-43, pp. 1169-1178, March 1995, and show a good performance whilst involving an acceptable complexity. However, their applicability is amongst others subject to the following considerable restrictions:

The overall transmission system has to be intersymbol-interference-free (i.e., first “Nyquist condition” is fulfilled).

Pure phase modulation (i.e., PSK, phase-shift keying) is required.

In particular the first condition of intersymbol-interference-free transmission cannot even approximately regarded as fulfilled in many practical applications (e.g. in frequency selective fading channels as in GSM mobile radio communication). In this context it is worth mentioning the WO 00/30312 A, which describes a frequency offset estimation for flat fading channels. Flat fading means that no intersymbol interference is admitted, i.e., the first Nyquist condition consequently is fulfilled. In the WO 00/30312 A the method is used for pilot-symbol-assisted modulation (PSAM), in which single pilot symbols are transmitted between data blocks. For transmission methods with intersymbol interference the method described in the WO 00/30312 A is not applicable.

The method described in U. Dettmar, “Combined Channel Estimation and Frequency Correction for Packet Oriented Mobile Communication Systems”, Proceedings of IEEE International Symposium on Personal, Indoor and Mobile Radio Communication (PIMRC'96), Taipeh, Taiwan, pp. 334-338, October 1996, admits dispersive channels and arbitrary linear modulations and conducts a joint least-squares estimation of channel impulse response and frequency offset. This method assumes the transmission of a training sequence which is known to the receiver. However, in case of relatively small frequency offsets and short training sequences, such as those employed e.g. in the GSM standard, this method can not achieve a sufficiently accurate estimation of the frequency offset.

Another decisive disadvantage of the mentioned methods is that these are optimized for the case in which the transmission channel is impaired by additive, usually, i.e. in the observed transmission spectrum, white noise (AWGN: Additive White Gaussian Noise). In many practical transmission systems this assumption is not even approximately fulfilled.

The task of the present invention therefore consists in providing a system and a method for an as reliable as possible estimation of the frequency offset in a carrier-based digital transmission system (e.g. GSM mobile radio communication system) under the following conditions:

an (approximately) linear modulation scheme is used, such as e.g. QAM (Quadrature Amplitude Modulation), PSK (Phase-Shift Keying) or GMSK (Gaussian Minimum-Shift Keying), wherein the latter modulation method can be approximated through filtered BPSK (binary phase-shift keying),

the received signal is available as so-called equivalent complex baseband signal,

the first Nyquist condition is not necessarily fulfilled (i.e., there may be intersymbol interferences)

no particular prior knowledge about the transmission channel is required; only the transmission of a training sequence for channel impulse response estimation at the receiver side is assumed,

the type of impairment (e.g. noise, adjacent or co-channel interference) in the transmission channel does not have to be known a priori,

the range of the expected frequency offset, in particular the maximum frequency offset occurring, has to be approximately known.

This task is solved by a method with the features of patent claim 1 and by a system with the features of patent claim 8.

The principle of the invention is,

(1) to derive from the received signal a number of N additional variants of the received signal (derivatives of the received signal), which are obtained through N different appropriate discrete frequency shifts of the original received signal,

(2) to appropriately process each of the N derivatives of the received signal for the reconstruction of the transmitted data sequence by equalization,

(3) to perform a (for practical reasons low-complexity) equalization of the N derivatives of the received signal,

(4) to determine during the equalization of the N derivatives of the received signal N suitable metrics which exactly or approximately reflect the quality of the equalized transmission symbols,

(5) to determine an estimate for the frequency offset in an appropriate manner by analysing the N metrics in combination with the N corresponding frequency shifts.

In contrast to some of the above-mentioned state-of-the-art methods, this invention does not perform an estimation based on a phase comparison.

The main application of the current invention is the estimation of the frequency offset between the carrier frequency of the received signal and the reference frequency of a coherent receiver. The invention enables under certain conditions to be specified later in more detail a significantly more accurate estimation of the frequency offset using the baseband signal in carrier-modulated digital transmission systems (e.g., GSM standard) than state-of-the-art methods and enables in connection with suitable measures for compensation of the frequency offset a significant improvement of the performance of the receiver with respect to the reconstruction of the transmitted data. This is particularly true for transmission in the presence of a strong co-channel and adjacent channel interfer, since in this case sometimes special methods for data reconstruction (e.g. interference cancellation, multi-user detection) are used which experience a strong performance degradation even in slowly time-variant channels (e.g. due to frequency offset). The method of this invention allows not only for frequency offset estimation in case of transmission via an AWGN channel but also in case of dispersive channels, where general linear modulation methods can be used, i.e., no restriction to phase modulation is given. A high performance is not only achieved for impairment by AWGN but also for interference as long as the other components of the receiver are designed for this case. For obtaining estimates of high quality with the method of this invention the training sequence lengths given in practical mobile radio communication systems such as GSM are completely sufficient.

Furthermore, the method is particularly well suited for data transmission in blocks, which is used in most mobile radio communication standards (e.g. GSM). In this case a block-based estimation of the frequency offset is beneficial because the properties of the transmission channel (e.g. in case of high velocity transmitter or the application of frequency hopping) change very strongly within a few blocks.

In an especially preferred embodiment of the method according to the invention the derivatives of the received signal are formed directly from the continuous-time received signal. In this case, the resulting quality of the subsequently determined estimate for the frequency offset is the highest possible.

Alternatively the derivatives of the received signal can be formed only after sampling of the continuous-time received signal. In this case, a single continuous-time filtering is sufficient which entails a reduced realization complexity in comparison to the first embodiment of the method.

Preferably the latter embodiment is only performed after a discrete-time pre-processing after sampling for the purpose of suppressing impairments, particularly interferences. Thus discrete-time preprocessing of only a single signal is necessary, which results in a further reduction of complexity.

Particularly preferred is a embodiment in which the estimate for the frequency offset is formed by means of the extreme value of a curve, which is determined by means of the metrics obtained from the N equalizations and the corresponding frequency offsets. The extreme value can be e.g. the apex of a parabola. With this measure an improvement of the accuracy of the estimate for the frequency offset can be achieved.

A further embodiment of the invention allows for the forming and the equalisation of the derivatives of the received signal being performed only in a subrange of the total received signal block. Thus fewer samples have to be equalized which reduces the complexity required for equalization.

Further advantageous embodiments of the invention may be gathered from the subclaims.

In the following, one embodiment of the invention will be described in more detail with reference to the attached figures. It is shown in:

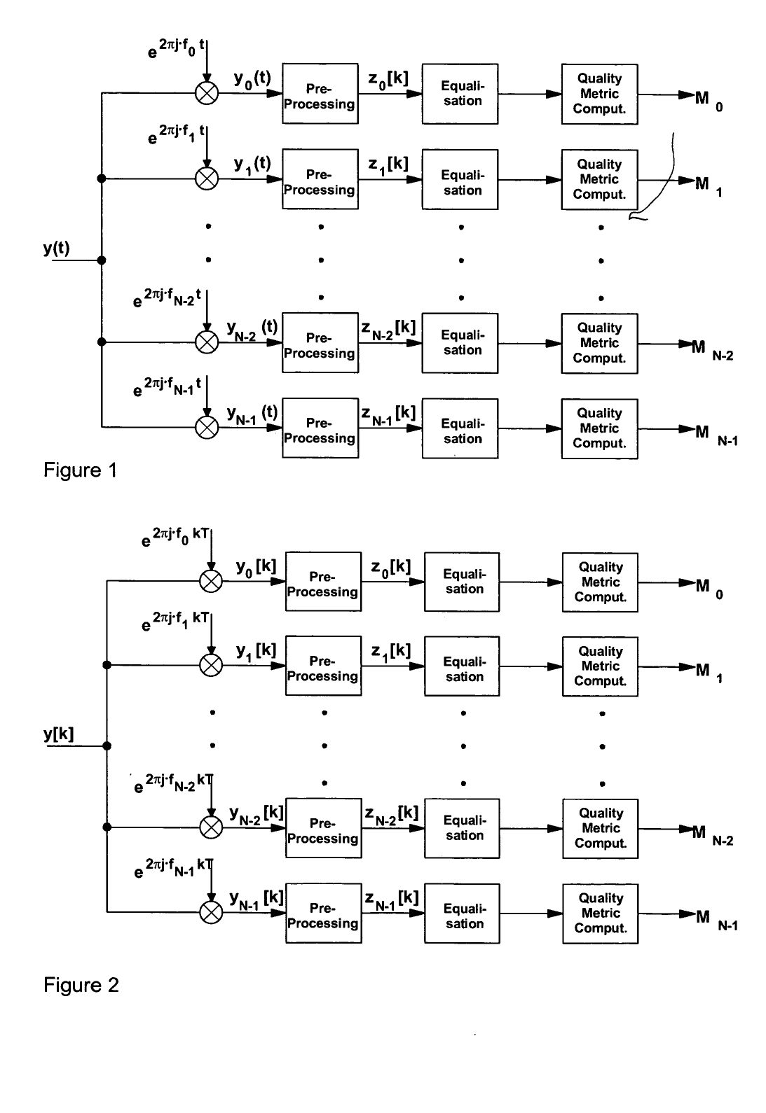

FIG. 1 a block diagram for the generation of the continuous-time derivatives of the received signal, their preprocessing includes sampling and equalization for obtaining metrics for frequency offset estimation;

FIG. 2 a block diagram for the generation of the discrete-time derivatives of the received signal, their preprocessing and equalization for obtaining metrics for frequency offset estimation;

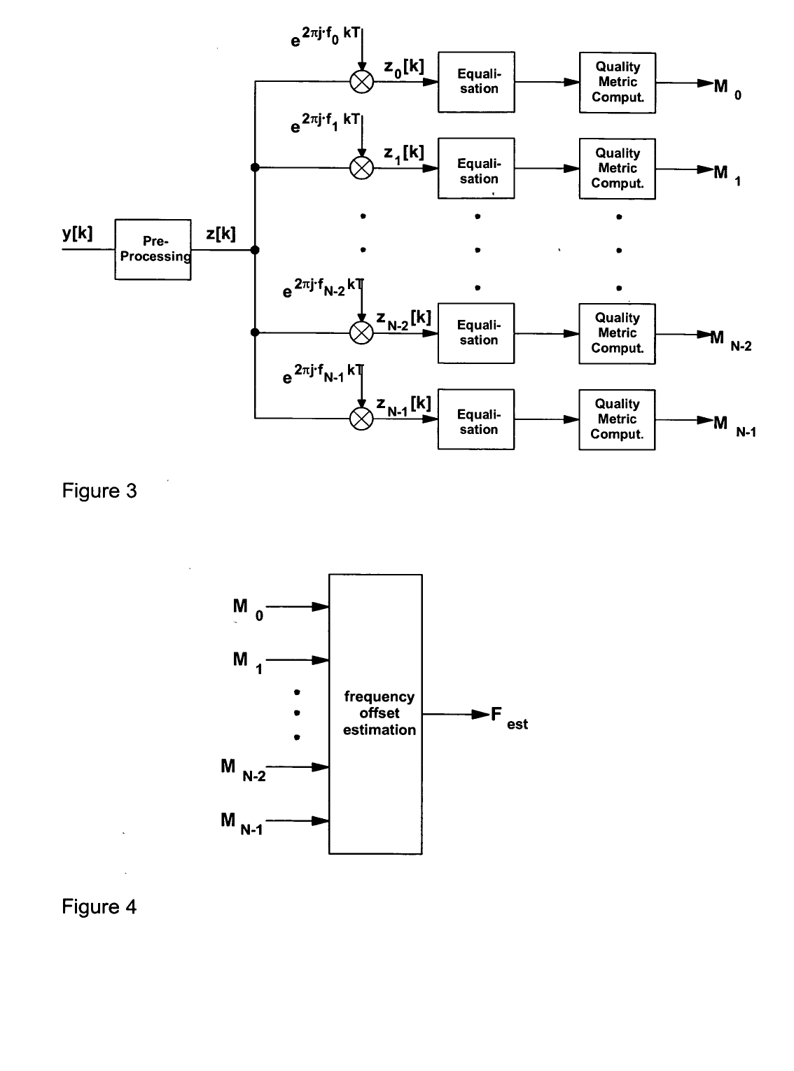

FIG. 3 a block diagram for preprocessing the discrete-time received signal, generating derivatives of the received signal and equalising for obtaining metrics for frequency offset estimation;

FIG. 4 a block diagram for obtaining an estimate for the frequency offset from the metrics Mᵥ;

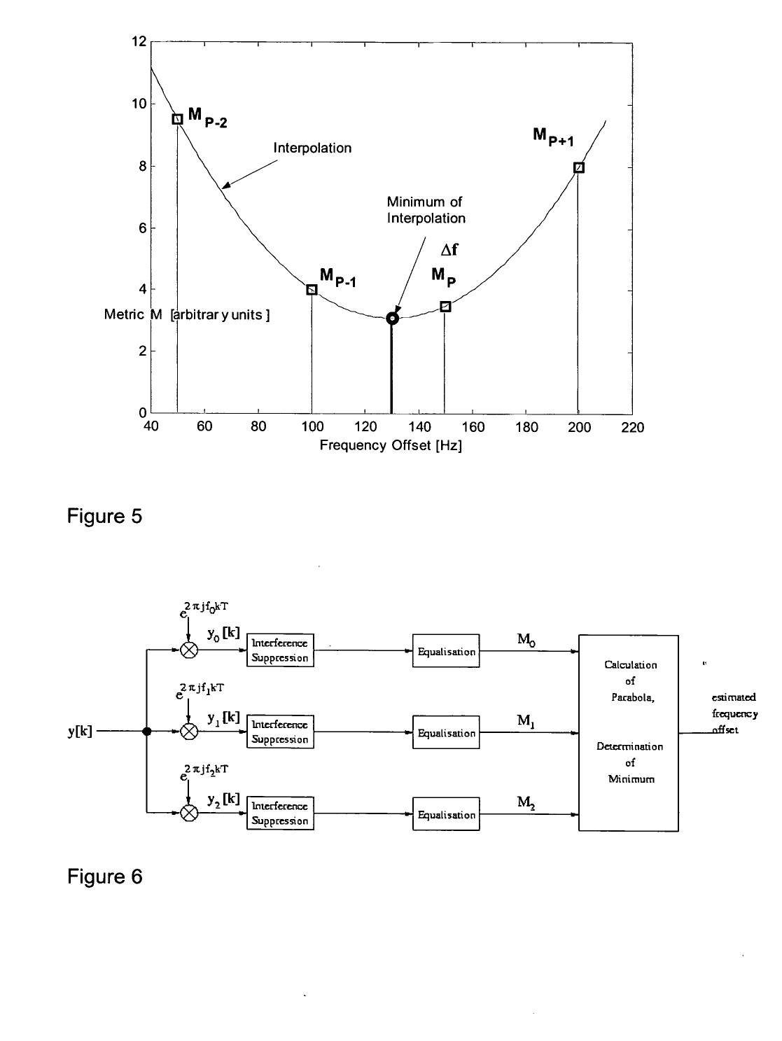

FIG. 5 a characteristic curve for determining an estimate for the frequency offset from the metrics Mᵥ; and

FIG. 6 a schematic block diagram of an embodiment of the system according to the invention.

In the following, it is assumed without loss of generality that the received signal in the so-called baseband representation is available either in continuous-time form y(t) or in discrete-time form as sequence y[k]. For the discrete-time representation as sequence y[k] equidistant sampling with sampling frequency 1/T, i.e., y[k]=y(t=kT) is assumed. Furthermore, it is assumed that the maximum magnitude Δfₘₐₓ of the expected frequency offset is known. Thus, the range of the expected frequency offset is rendered
Δf ε[−Δfₘₐₓ,+Δfₘₐₓ]

1.) Generation of the Derivatives of the Received Signal

First, N discrete frequency offsets fᵥ ε{f₀, f₁, . . . , f_{N-1}} are determined which cover the above-mentioned range in a suitable manner. For a frequency offset which is e.g. uniformly distributed in the interval Δf ε[−Δfₘₐₓ,+Δfₘₐₓ] a preferable choice for the frequency offsets fᵥ is.

$$\begin{matrix}{f}_{v} = - Δ {f}_{max} + ( v + 0.5 ) \cdot \frac{2 Δ {f}_{max}}{N} , & v ∈ \{ 0 , 1 , … N - 1 \}\end{matrix} \qquad ( 1 )$$

Otherwise the selection of the fᵥ can be based on the probability density function of the expected frequency offsets, wherein the nodes can also be chosen non-equi-distant at random. The choice of the value N is based on the available signal processing resources of the receiver as well as the desired accuracy of the estimate of the frequency offset.

By means of these values N signals yᵥ(t) are derived from the received signal, see FIG. 1, which are obtained by imposing the frequency shifts fᵥ onto the original signal y(t):
yᵥ(t)=y(t)·e^{j·2πf}^{ᵥ}^{t} (2)

For Δfₘₐₓ<<1/T this frequency shift can also be imposed onto the signal in discrete-time form y[k] with a similar effect:
yᵥ[k]=y[k]·e^{j·2πf}^{ᵥ}^{kT}, (3)

cf. FIG. 2. Alternatively, the corresponding operation of frequency shift can be applied directly to the carrier-frequency signal, which however is very inefficient for practical reasons (complexity of down-conversion of the signal to baseband increases by a factor of N).

2.) Preprocessing for Equalization of the Derivatives of the Received Signal

Now, each of these signals is preprocessed in a suitable manner in accordance with the employed equalization method (see Item 3: Equalization). This preprocessing, e.g. matched filtering, sampling, channel estimation, above all digital filtering for the suppression of impairment signals such as interference, is performed in accordance with the state of the art and is not the subject matter of this invention.

The sequences rendered after preprocessing are denoted by zᵥ[k].

Depending on the size of the expected frequency offset Δf and the number of samples used for estimation it may be advantageous to perform the preprocessing (e.g. digital prefiltering of the signal) before the frequency shifts are imposed, see FIG. 3. Depending on the application this may lead to a significant complexity reduction while the estimation accuracy is hardly affected. As an example, the digital prefiltering for the purpose of interference suppression is to be mentioned.

3.) Equalization of the Derivatives of the Received Signal

Now, the equalization of the discrete-time derivatives zᵥ[k] of the received signal is performed. For this, in principle, all known equalization methods can be used such as e.g. linear equalization described in e.g. J. G. Proakis, “Digital Communications”, McGraw-Hill, New York, 1989, decision-feedback equalization (DFE) described in e.g. P. Monsen, “Feedback Equalization for Fading Dispersive Channels”, IEEE Trans. Information Theory, IT -17, pp. 56-64, January 1971, or maximum-likelihood sequence estimation (MLSE) described in e.g. G. D. Forney, Jr., “Maximum-Likelihood Sequence Estimation of Digital Sequences in the Presence of Intersymbol Interference”, IEEE Trans. Information Theory, IT -18, pp. 363-378, May 1972, as well as reduced-state and reduced-complexity versions of it (e.g. reduced-state sequence estimation (RSSE), described in e.g. M. V. Eyuboglu and S. U. Qureshi, “Reduced-State Sequence Estimation with Set Partitioning and Decision-Feedback”, IEEE Trans. Comm., COM-36, pp. 401-409, April 1988, decision-feedback sequence estimation (DFSE), described in e.g. A. Duel-Hallen and C. Heegard, “Delayed Decision-Feedback Sequence Estimation”, IEEE Trans. Comm., COM-37, pp. 428-436, May 1989).

The selection of the method is based on the available signal processing resources of the receiver as well as the desired accuracy of the frequency offset estimation. In general low-complexity methods (e.g. DFE or RSSE) are preferably employed.

4.) Metric for Estimation of the Reliability of the Equalized Transmit Symbols

The primary aim of the equalization is to obtain one scalar metric Mᵥ per sequence zᵥ[k], which allows to estimate the reliability of the equalized transmit symbol sequence (or a part thereof). This means the applied frequency shifts fᵥ are associated with the corresponding metrics Mᵥ.

It is necessary that there is (at least approximately) a monotonic relation between the metric and the reliability of the (entire or partial) sequence of equalized transmitted symbols. Thereby, the absolute value of the metrics Mᵥ is of no importance since only the position of the minimum has to be determined which represents the negative estimate of the frequency offset (see below).

In the following two examples for suitable metrics will be presented:

Soft-Output Equalization:

In soft-output equalization, in addition to the estimates of the data symbols, estimates for their reliability are calculated. For this, e.g. the maximum a posteriori symbol-by-symbol estimation (MAPSSE) algorithm or the soft output Viterbi algorithm (SOVA) can be applied.

Estimation of an average bit error rate Pᵥ per signal sequence zᵥ[k] of length K with

$$\begin{matrix}{M}_{v} = {P}_{v} = \frac{1}{K} \cdot {\sum }_{k = 0}^{K - 1} {p}_{v} [ k ] , & v ∈ \{ 0 , 1 , … , N - 1 \} ,\end{matrix} \qquad ( 4 )$$

pᵥ[k]: estimated error probability for the kth symbol of the data sequence

Soft-Output or Hard-Output Equalization:

In hard-output equalization only the estimates of the data symbols are calculated. By selecting the data symbols with the highest probability, hard output can also be formed in soft-output equalization.

Estimation of the average noise variance Vᵥ per symbol sequence zᵥ[k] by forming the difference between signal sequence zᵥ[k] and corresponding reconstructed wanted signal component ûᵥ[k]. Assuming a linear transmission system, the following holds:

$$\begin{matrix}{M}_{v} = {V}_{v} \\ = \frac{1}{K} \cdot {\sum }_{k = 0}^{K - 1} {\vert {z}_{v} [ k ] - {\hat{u}}_{v} [ k ] \vert}^{2} \\ = \frac{1}{K} \cdot {\sum }_{k = 0}^{K - 1} {\vert {z}_{v} [ k ] - {\sum }_{μ = 0}^{{L}_{v} - 1} {\hat{a}}_{v} [ k - μ ] \cdot {\hat{h}}_{v} [ μ ] \vert}^{2} ,\end{matrix} \qquad ( 5 )$$

with âᵥ[k]: estimated kth transmit symbol of the sequence zᵥ[k] (either hard decision or soft decision),

ĥᵥ[k] estimated discrete-time overall impulse response corresponding to sequence zᵥ[k],

Lᵥ: number of coefficients of impulse response ĥᵥ[k]

Apart from the scaling factor 1/K this value is automatically generated as accumulated metric of the estimated path in the trellis diagram of the equalization algorithm in case of equalization with MLSE, RSSE, DFSE, or DFE and therefore lends itself as comparatively low-complexity solution.

The above-mentioned metrics should be considered only as examples and in principle a plurality of further metrics can be constructed which also have the desired monotonic relationship to the reliability of the estimated data sequence.

With respect to the number of equalized transmit symbols it may not be necessary to evaluate the entire symbol sequence within one block. Depending on the parameters of the respective application it may thus be sufficient to equalize only a part of each signal block for achieving the desired high accuracy of the estimate for the frequency offset (or low error variance). For example, for application of the method to a receiver for the GSM system an analysis within a sub-range containing the training sequence amongst others may be sufficient.

5.) Determination of an Estimate for the Frequency Offset by Analysing of the Metrics.

After completion of step 4 for the N frequency shifts fᵥ respective scalar metrics Mᵥ are available, on the basis of which an estimate for the frequency offset, see FIG. 4, is now determined. For ΔfT<<1
z[k]=\tilde{z}[k]·e^{j2πΔfkT}, (6)
holds approximately for the output signal of the preprocessing stage, wherein \tilde{z}[k] represents the signal after the preprocessing stage for ideal frequency synchronization. Therefore, for the vth derivative of the received signal
zᵥ[k]=\tilde{z}[k]·e^{j2π(Δf+f}^{ᵥ}^{)kT}, (7)
is rendered which means that for the derivative zᵥ[k] of the received signal an effective frequency offset Δf+fᵥ is effective. Since a frequency offset has a degrading effect on the reliability of the equalization, for continuous variation of the frequency shift f it can be expected that the minimum of the corresponding metrics M(f) is rendered for f≈−Δf. Thus, in this case, the location of the minimum of the curve M(f) directly allows for drawing conclusions on the frequency offset given. If only discrete frequencies fᵥ are considered, which is inevitable in practice, the determination of the argument of the minimum of the sequence Mᵥ=M(fᵥ) also allows for obtaining a reliable estimate of the frequency offset as long as a sufficiently large number N of discrete frequency shifts is used. An estimate of even higher quality can be obtained in the discrete case if a curve G(f) is calculated on the basis of the tupels (fᵥ, Mᵥ) and the argument corresponding to its minimum is chosen as the estimate for the (negative) frequency offset.

For derivation of a favourable curve G(f) first again a continuous variation of the frequency shift f is assumed. Therefore, now the sequences
z^{f}[k]=\tilde{z}[k]·e^{j2π(Δf+f)kT} (8)
are considered, see Eq. (7). If the path metric of the best path of a Viterbi equalizer is chosen as metric M(f), assuming correct detection of the transmitted data symbols, M(f) can be approximated by

$$\begin{matrix}M ( f ) = \frac{1}{K} {\sum }_{k = 0}^{K - 1} {\vert ( \overline{z} [ k ] + n [ k ] ) \cdot {ⅇ}^{j 2 π ( Δ f + f ) k T} - \overline{z} [ k ] \vert}^{2} \\ \approx \frac{1}{K} {\sum }_{k = 0}^{K - 1} {\vert \overline{z} [ k ] \cdot ( {ⅇ}^{j 2 π ( Δ f + f ) k T} - 1 ) \vert}^{2} + \frac{1}{K} {\sum }_{k = 0}^{K - 1} {\vert n [ k ] \vert}^{2}\end{matrix} \qquad ( 9 )$$

wherein \overline{z}[k] and n[k] refer to the noise free component of the signal \tilde{z}[k] and the noise component after the preprocessing, respectively. Thereby,

$$\frac{1}{K} {\sum }_{k = 0}^{K - 1} \overline{z} [ k ] \cdot ( {ⅇ}^{j 2 π ( Δ f + f ) k T} - 1 ) \cdot {n}^{*} [ k ] \to 0 \qquad ( 10 )$$

has been assumed, which is justified for K>>1 (•* means complex conjugation). Using the approximation e^{x}=1+x for |x|<<1, (9) can be transformed to

$$M ( f ) \approx \frac{{( 2 π T )}^{2}}{K} {\sum }_{k = 0}^{K - 1} {\vert \overline{z} [ k ] \vert}^{2} {k}^{2} \cdot {( Δ f + f )}^{2} + \frac{1}{K} {\sum }_{k = 0}^{K - 1} {\vert n [ k ] \vert}^{2} \qquad ( 11 )$$

This means an expression of the form
G(f)=a·f²+b·f+c (12)
has been rendered, with suitable constants a>0, b,c>0 and thus the equation of a convex parabola. Thus for a more accurate estimation of the frequency off-set it offers itself to determine a suitable parabola on the basis of the tupels (fᵥ, Mᵥ), wherein its apex (i.e. the argument for which G(f) is minimised) −b/(2a) can serve directly as estimate −Δ\hat{f} for −Δf. As criterion for the determination of the parabola e.g. the sum of error squares

$${\sum }_{v = 0}^{N - 1} {\vert G ( {f}_{v} ) - {M}_{v} \vert}^{2}$$

can be used. The minimimization of this criterion using regression calculation leads to a linear system of equations for determination of the parameters a, b, c.

Alternatively, the curve G(f) can also be modeled as higher order polynomial, transcendent function, etc, which is advantageous if the metrics Mᵥ are not derived from a Viterbi equalizer but according to Eq. (4) as average bit error probabilities or according to another rule, since in that case the actual metric dependence can be better approximated. For the determination of parameters of function G(f) in principle arbitrary methods for curve interpolation can be used. The general procedure for estimation of the frequency offset based on G(f) is illustrated in FIG. 5.

With regard to FIG. 6, as embodiment of a system according to the invention, frequency offset estimation for a transmission via a dispersive channel with intersymbol interference given is considered. Frequency offset estimation according to the proposed method is performed, wherein for preprocessing prior to N different trellis-based equalizations and channel estimations an interference suppression according to the teaching of the EP 00128664.0 bearing the title “Verfahren zur Interferenzunterdrückung für TDMA- und/oder FDMA-Übertragung”by the same applicants as the current invention is performed. The input to the N equalizations and channel estimations is the output zᵥ[k], v ε {0, 1, . . . , N−1} of the interference suppression methods. In order to achieve a high performance and moderate system complexity at the same time, N may be chosen to e.g. 3, wherein for obtaining the estimate for the frequency offset a postprocessing of the tupels (f₀, M₀), (f₁, M₁), (f₂, M₂) according to the parabola curve is performed which is unambiguously determined by the three tupels. After the offset estimation, the offset is compensated. The frequency-offset-compensated signal is then exposed to a conventional trellis-based equalization.

List of employed variables:

f: frequency

Δf: frequency offset

Δ\hat{f}: estimated frequency offset

Δfₘₐₓ: maximum frequency offset

fᵥ: discrete frequency shift

N: number of frequency shifts

y(t): continuous-time received signal

y[k]: discrete-time received signal

\tilde{y}[k]: received signal for no frequency offset

\overline{y}[k]: corresponding noise free signal

yᵥ(t): continuous-time derivative of the received signal

yᵥ[k]: discrete-time derivative of the received signal

z[k]: received signal after interference suppression

\tilde{z}[k]: received signal after interference suppression in the absence of frequency offset

\overline{z}[k]: corresponding noise free signal component

n[k]: noise component

zᵥ[k]: derivative of signal after interference suppression

z^{f}[k]: derivative of signal after interference suppression in case of continuous variation of frequency shift

Mᵥ: metric

M(f): metric in case of continuous variation of frequency shift

T: symbol interval

G(f): function for interpolation

K: sequence length of processed sequence

âᵥ[k]: kth transmitted symbol of sequence zᵥ[k]

ĥᵥ[k]: estimated discrete-time overall impulse response for sequence zᵥ[k]

Lᵥ: number of coefficients of impulse response ĥᵥ[k]

1-8. (canceled)

9: A method for frequency offset estimation for TDMA (time division multiple access) and/or FDMA (frequency division multiple access) transmission, which can be at least approximately modeled as pulse amplitude modulation and in which the first Nyquist condition is not fulfilled, comprising the following steps:
forming a number N of further variants of the received signal, so-called derivatives of the received signal, by N different discrete frequency shifts of the original received signal;
processing the derivatives of the received signal for reconstruction of the transmitted symbol sequence through trellis-based equalization;
performing the trellis-based equalization of the N derivatives of the received signal;
determining N metrics for the N derivatives of the received signal in the course of the trellis-based equalization reflecting at least approximately the reliability of the estimated transmitted symbols; and
determining an estimate for the frequency offset by analysing the N metrics in connection with the corresponding frequency shifts.

10: Method according to claim 9, characterized in that the derivatives of the received signal are formed directly from the continuous-time received signal.

11: Method according to claim 9, characterized in that the derivatives of the received signal are formed after sampling of the continuous-time received signal

12: Method according to claim 11, characterized in that the discrete-time derivatives of the received signal are formed only after a discrete-time preprocessing carried out after sampling for the purpose of suppressing impairments, in particular interferences.

13: Method according to claim 9, characterized in that the discrete-time derivatives of the received signal are formed only after a discrete-time preprocessing carried out after sampling for the purpose of suppressing impairments, in particular interferences.

14: Method according to claim 9, characterized in that an estimate for the frequency offset is formed by means of the extreme value of a curve which is determined on the basis of N metrics obtained by N equalizations and the corresponding frequency shifts.

15: Method according to claim 14, characterized in that the extreme value is formed from the apex of a parabola.

16: Method according to claim 9, characterized in that the generation and the equalisation of the derivatives of the received signal are performed only in a partial area of the received signal block.

17: System for frequency offset estimation for TDMA and/or FDMA transmission, which can be at least approximately modeled as pulse amplitude modulation and where the first Nyquist condition is not fulfilled, comprising:
a device for forming a number N of further variants of the received signal, so-called derivatives of the received signal, by N different discrete frequency shifts of the original received signal;
a device for processing the derivatives of the received signal for reconstruction of the transmitted symbol sequence through trellis-based equalization;
a device for performing the trellis-based equalization of the N derivatives of the received signal;
a device for determining N metrics for the N derivatives of the received signal in the course of the trellis-based equalization reflecting at least approximately the reliability of the estimated transmitted symbols; and
a device for determining an estimate for the frequency offset by processing the N metrics in connection with the corresponding frequency shifts.
